(19) United States
(12) Patent Application Publication
(10) Pub. No.: US 2012/0103802 A1
(43) Pub. Date: May 3, 2012

(54) THIN FILM DEPOSITING APPARATUS

(75) Inventors: Woo-Seok CHEONG, Daejeon (KR); Yeong-Shin Kim, Daejeon (KR)

(73) Assignees: ELECTRONICS AND TELECOMMUNICATIONS RESEARCH INSTITUTE, Daejeon (KR); Yeong-Shin Kim, Daejeon (KR)

(21) Appl. No.: 13/182,759

(22) Filed: Jul. 14, 2011

(30) Foreign Application Priority Data
Oct. 27, 2010 (KR) 10-2010-0105302

(51) Int. Cl. C23C 14/34

(52) U.S. Cl. 204/298.11; 204/298.02

(57) ABSTRACT

Provided is a thin film depositing apparatus. The thin film depositing apparatuses includes: a chamber where a process is performed on a subject to be processed; a plurality of supporters supporting the subject to be processed in the chamber; at least one sputter gun inducing a first plasma below or on the subject to be processed between the plurality of supporters; and a plurality of inductive coupled plasma tubes inducing a more expanded second plasma than the first plasma between the sputter gun and the subject to be processed.

### CROSS-REFERENCE TO RELATED APPLICATIONS

This U.S. non-provisional patent application claims priority under 35 U.S.C. §119 of Korean Patent Application No. 10-2010-0105302, filed on Oct. 27, 2010, the entire contents of which are hereby incorporated by reference.

### BACKGROUND OF THE INVENTION

The present invention disclosed herein relates to a thin film depositing apparatus, and more particularly, to a thin film depositing apparatus depositing a thin film on a subject to be processed.

Recently, Research and Development (R&D) for obtaining a high-performance thin film having excellent surface characteristics in various industry fields is actively in progress. Only when mass production of the high-performance thin film is possible, its price competitiveness may be improved. However, a typical thin film depositing apparatus requires a high-degree vacuum to minimize impurity and also requires an expensive microwave to activate deposition particles during forming of a high-performance thin film. As a result, its productivity may be reduced.

### SUMMARY OF THE INVENTION

The present invention provides a thin film depositing apparatus obtaining a high-performance thin film.

The present invention also provides a thin film depositing apparatus increasing or maximizing productivity.

Embodiments of the present invention provide thin film depositing apparatuses including: a chamber where a process is performed on a subject to be processed; a plurality of supporters supporting the subject to be processed in the chamber; at least one sputter gun inducing a first plasma below or on the subject to be processed between the plurality of supporters; and a plurality of inductive coupled plasma tubes inducing a more expanded second plasma than the first plasma between the sputter gun and the subject to be processed.

In some embodiments, the plurality of inductive coupled plasma tubes may include a rod electrode.

In other embodiments, the supporters may include a roller transferring the subject to be processed.

In still other embodiments, the roller may be disposed parallel to the rod electrode.

In even other embodiments, the rod electrode may guide the first plasma.

In yet other embodiments, the thin film depositing apparatuses may further include a plurality of shutters between the plurality of inductive coupled plasma tubes and the subject to be processed.

In further embodiments, the plurality of shutters may expose the subject to be processed to the first plasma.

In still further embodiments, the plurality of shutters may have end portions bent between the plurality of inductive coupled plasma tubes.

In even further embodiments, the end portions may be bent with an acute angle when the sputter gun is one.

In yet further embodiments, the thin film depositing apparatuses may further include a target generating deposition particles through the first plasma on the sputter gun.

In yet further embodiments, the sputter gun may have a width of 5 nm to 20 cm and a length of 30 cm to 300 cm.

In yet further embodiments, when there are a plurality of sputter guns, they are disposed with a center distance of 5 cm to 20 cm.

In yet further embodiments, the plurality of sputter guns may be disposed to face each other at a tilt angle of 10° to 45°.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1A and 1B are sectional views illustrating a thin film depositing apparatus according to the embodiment of the inventive concept;

FIG. 2 is an enlarged view of a portion A of FIG. 1A;

FIG. 3 is a plan view of FIG. 1A;

FIG. 4 is a graph illustrating an electron density change in a first plasma and a second plasma according to a second high frequency power;

FIG. 5 is a view of measuring results used to compare a sheet resistance of a second metal thin film generated from the first plasma with that generated from the first and second plasmas;

FIGS. 6A and 6B are sectional views illustrating a thin film depositing apparatus according to another embodiment of the present invention; and

FIG. 7 is an enlarged view of an area B of FIG. 6A.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. Like reference numerals refer to like elements throughout.

While specific terms were used, they were not used to limit the meaning or the scope of the present invention described in Claims, but merely used to explain the present invention. The meaning of “include,” “comprise,” “including,” or “comprising,” specifies a property, a region, a fixed number, a step, a process, an element and/or a component but does not exclude other properties, regions, fixed numbers, steps, processes, elements and/or components. Since preferred embodiments are provided below, the order of the reference numerals given in the description is not limited thereto.

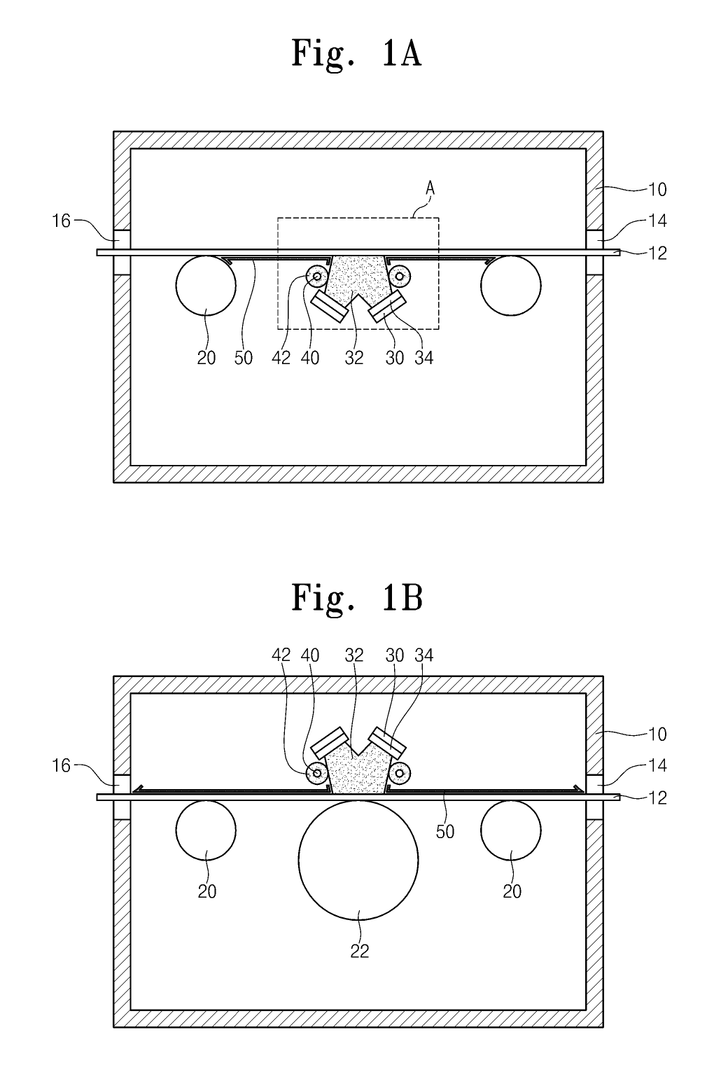

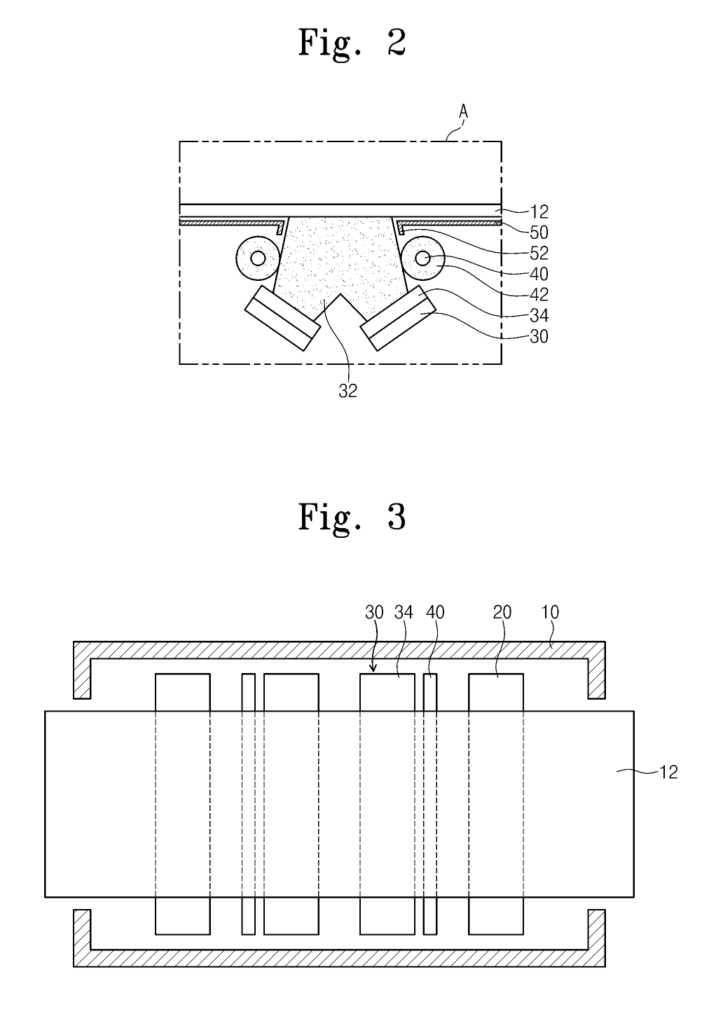

FIGS. 1A and 1B are sectional views illustrating a thin film depositing apparatus according to the embodiment of the inventive concept. FIG. 2 is an enlarged view of a portion A of FIG. 1A. FIG. 3 is a plan view of FIG. 1A.

Referring to FIGS. 1A through 3, the thin film depositing apparatus according to the embodiment of the inventive concept may include a plurality of sputter guns 30 below or on a subject 12 to be processed and a plurality of inductive coupled plasma tubes 40 between the plurality of sputter guns 30 and the subject 12 to be processed.

The plurality of sputter guns 30 sputters deposition particles from targets 34 by inducing a first plasma 32. The plurality of inductive coupled plasma tubes 40 may induce a more extended second plasma than the first plasma 32. The second plasma 42 may uniformly mix the deposition particles sputtered from the targets 34. The second plasma 42 may increase an ionization rate of an inert gas charged from the first plasma 32. Accordingly, the since thin film depositing apparatus may manufacture a large quantity of high-performance thin films, productivity may be increased or maximized.

A chamber 10 provides a separate space from the external so that it may minimize a pollutant that may occur in a high-performance thin film. The chamber 10 may include a pumping system (not shown) maintaining its inside to be a vacuum pressure of about 0.1 mTorr to about 100 mTorr. Additionally, the chamber 10 may be filled with an inert gas such as Ar, which is a source gas of the first plasma 32 and the second plasma 42. The chamber 10 may include an inlet 14 and an outlet 16 through which the subject 12 to be processed enters and exits.

Supporters 20 may include a roller. The supporters 20 may support the subject 12 to be processed at the both sides of each of the plurality of sputter guns 30 and inductive coupled plasma tubes 40. The subject 12 to be processed may include a flat substrate or a flexible film. The supporters 20 may move both the flat substrate and the flexible film. The subject 20 to be processed may be supported by the supporters 20 in the chamber 10. The flexible film may continuously transfer in the chamber 12 through the supporters 20. The flexible film may continuously transfer through a roll-to-roll way. The supporters 20 may further include a large diameter roller 22 supporting the subject 12 to be processed when the sputter guns 30 and the inductive coupled plasma tubes 40 are disposed on the subject 12 to be processed.

The plurality of sputter guns 30 may induce the first plasma 32 through a first high frequency power supplied from the external of the chamber 12. The plurality of sputter guns 30 may have a width of about 5 cm to about 20 cm and a length of about 30 cm to about 300 cm. The plurality of sputter guns 30 may be disposed to face each other at a tilt angle of about 10° to 45° with respect to a horizontal plane. The distance between the centers of the plurality of sputter guns 30 may be about 5 cm to about 20 cm. The targets 34 may be disposed on the plurality of sputter guns 30. The targets 34 may include a source material of a thin film formed on the subject 12 to be processed. For example, the targets 34 may include metals such as tungsten, aluminum, titanium, cobalt, nickel, and molybdenum and ceramic such as a silicon oxide layer. The first high frequency power applied to the plurality of sputter guns 30 may charge an inert gas such as Ar into a positive ion of a plasma state on the plurality of sputter guns 30.

The inert gas of a plasma state may be sputtered into the targets 34. A plurality of permanent magnets (not shown) focusing a positive ion of a plasma state may be further disposed on the rear sides of the plurality of sputter guns 30 facing the targets 34. The first plasma 32 sputters deposition particles constituting a thin film on the subject 12 to be processed from the targets 34. At this point, the first plasma 32 may be constrained between the plurality of inductive coupled plasma tubes 40.

The plurality of inductive coupled plasma tubes 40 may induce the second plasma 42 through a second high frequency power supplied from the external of the chamber 12. The plurality of inductive coupled plasma tubes 40 may be disposed parallel to the supporters 40. The plurality of inductive coupled plasma tubes 40 may include a rod electrode. Accordingly, the rod electrode may be disposed parallel to the supporters 20 and vertical to a transfer direction of the subject 12 to be processed, which is transferred by the supporters 20. The rod electrode may include a coil to which the second high frequency power is applied and a cover of a glass material surrounding the coil.

The plurality of inductive coupled plasma tubes 40 may be disposed between the subject 12 to be processed and the sputter guns 30. The plurality of inductive coupled plasma tubes 40 may guide the first plasma 32. The first plasma 32 may be induced between the plurality of inductive coupled plasma tubes 40. Accordingly, the second plasma 42 may be induced in a broader area than the first plasma 32.

Shutters 50 may be disposed between the subject 12 and the plurality of inductive coupled plasma tubes 40. When the plurality of inductive coupled plasma tubes 40 are disposed on the subject 12 to be processed as shown in FIG. 1B, the shutters 50 may protect the subject 12 to be processed from impurities laminated from the inductive coupled plasma tubes 40. Additionally, the shutters 50 may protect the subject 12 to be processed from the second plasma 42 generated at a short distance from the plurality of inductive coupled plasma tubes 40. The end portions 52 of the shutters 50 may be bent toward the inductive coupled plasma tubes 40 and the sputter guns 30. The end portions 52 of the shutters 50 may be bent with an obtuse angle of more than 90°.

The second plasma 42 may be induced around the inductive coupled plasma tubes 40. Although not shown in FIGS. 1A, 1B, and 2, the second plasma 42 may be induced overlapping the first plasma 32 between the inductive coupled plasma tubes 40. In more detail, the second plasma 42 may be induced between the targets 34 and the shutters 50 and between the inductive coupled plasma tubes 40. The second plasma 42 may uniformly mix deposition particles sputtered from the first plasma 32. The second plasma 42 may overlap the first plasma 32 between the inductive coupled plasma tubes 40. The second plasma 42 may increase an ionization rate of an inert gas ionized from the first plasma and the deposition particles. Accordingly, the second plasma 42 may improve a characteristic of a thin film formed on the subject 12 to be processed.

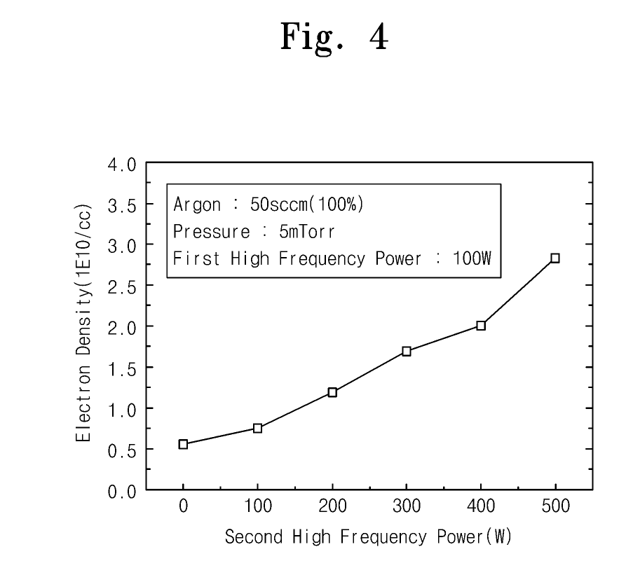

FIG. 4 is a graph illustrating an electron density change in a first plasma and a second plasma according to a second high frequency power.

Referring to FIGS. 1A through 4, an electron density of the first plasma 32 and the second plasma 42 may be increased in linearly proportion to the second high frequency power applied to the inductive coupled plasma tubes 40. As the electron density is increased, deposition particles are uniformly mixed and an ionization rate of an inert gas and the deposition particles may be increased. Accordingly, a high-performance thin film may be obtained on the subject 12 to be processed. Here, the chamber 10 may be filled with Ar gas, which is an inert gas supplied with a gas flow rate of about 50 sccm at a vacuum pressure of about 5 mTorr. The first high frequency power applied to the sputter guns 30 may be about 100 W.

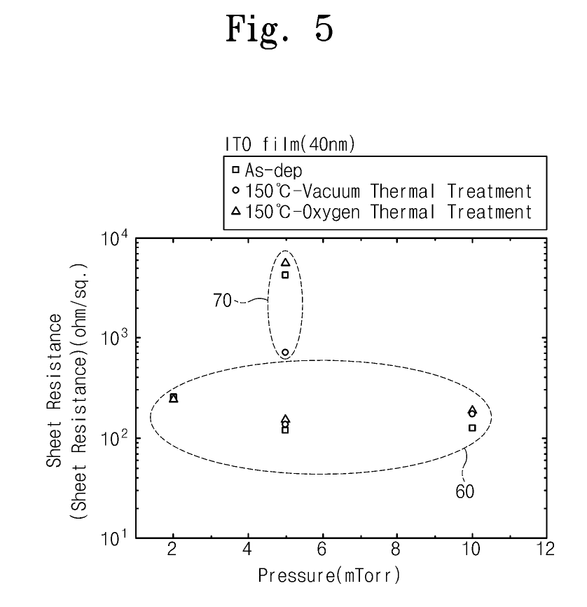

FIG. 5 is a view of measuring results used to compare a sheet resistance of a second metal thin film generated from the first plasma 32 with that generated from the first and second plasmas 32 and 42.

Referring to FIGS. 1A through 5, first metal thin films 60 obtained from the first and second plasmas 32 and 42 may have lower sheet resistance than second metal thin films 70 obtained from the first plasma 32. Here, the first metal thin films 6 and the second metal thin films 70 may include an Indium-Tin Oxide (ITO) having a thickness of about 40 nm. The first high frequency power is about 100 W and the second high frequency power is about 500 W. In relation to the first metal thin films 60 and the second metal thin films 70, their sheet resistances may be measured as deposited at a room temperature, measured after vacuum heat treatment of 150° C., or measured after oxygen heat treatment of 150° C.

Since the first metal thin films 60 have a lower sheet resistance than the second metal thin films 70, they have more excellent electrical characteristics. The first metal thin films 60 may be formed more uniform and denser than the second metal thin films 70. Additionally, the first metal thin films 60 may have lower impurity than the second metal thin films 70. For example, when an internal pressure of the chamber 10 is less than 10 mTorr, the first metal thin layers 60 may have a sheet resistance of about 10² Ω/cm². Moreover, the second metal thin films 70 may have a sheet resistance of about 10³ Ω/cm². Under a vacuum pressure of about 5 mTorr, the first metal thin films 60 may have lower sheet resistance, which is about one tenth of the second metal thin films 70.

Accordingly, the thin film depositing apparatus according to an embodiment of the present invention may obtain a high-performance thin film from the first and second plasmas 32 and 42.

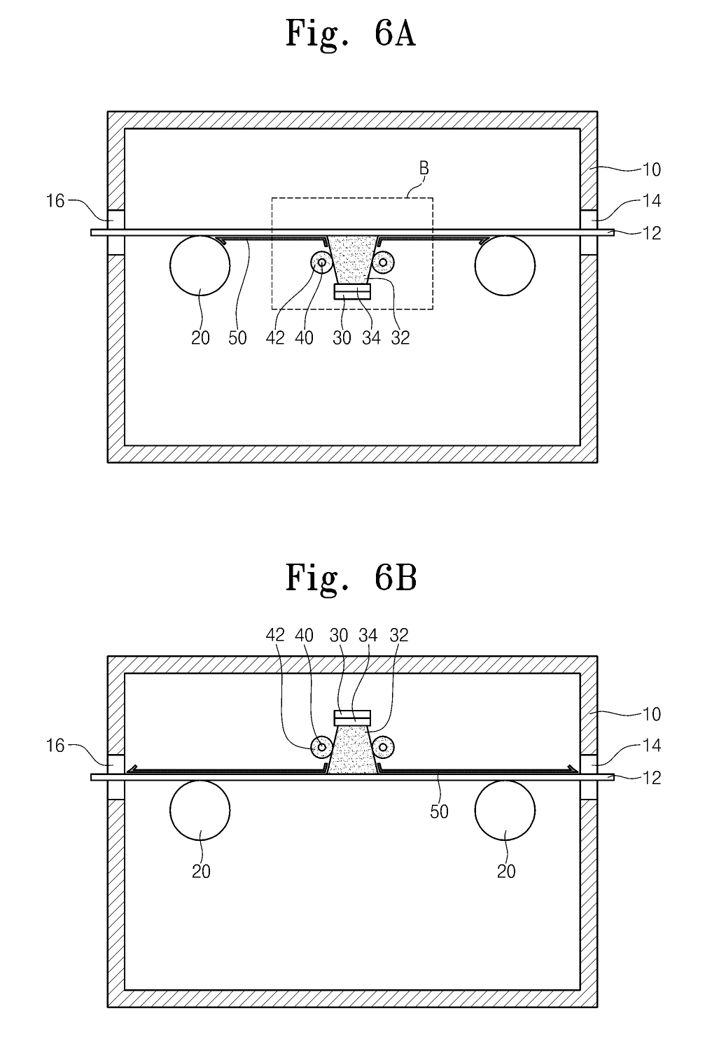

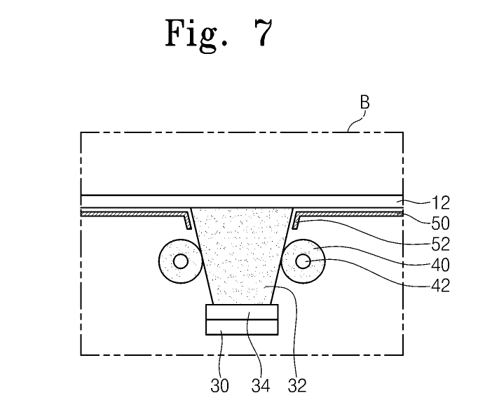

FIGS. 6A and 6B are sectional views illustrating a thin film depositing apparatus according to another embodiment of the present invention. FIG. 7 is an enlarged view of an area B of FIG. 6A.

Referring to FIGS. 6A and 7, the thin film depositing apparatus according to another embodiment may include a sputter gun 30 below or on a subject 12 to be processed and a plurality of inductive coupled plasma tubes 20 between the sputter gun 30 and the subject 12 to be processed.

The sputter gun 30 may be disposed parallel to the subject 12 to be processed. The sputter gun 30 may induce a first plasma 32 through a first high frequency power supplied from the external of the chamber 10. The sputter gun 30 may sputter deposition particles from a target 34 through the first plasma 32. The inductive coupled plasma tubes 20 may induce a more expanded second plasma 42 than the first plasma 32 through a second high frequency power supplied from the external. The second plasma 42 may uniformly mix deposition particles sputtered from the target 34. The second plasma 42 may increase an ionization rate of an inert gas charged from the first plasma 32. Accordingly, the thin film depositing apparatus according to another embodiment of the present invention may obtain a high-performance thin film.

Shutters 50 may be disposed between the plurality of inductive coupled plasma tubes 40 and the subject 12 to be processed. The shutters 50 may protect the subject 12 to be processed from the second plasma 42. The shutters 50 may expose the subject 12 to be processed to the first plasma 32. The end portions 52 of the shutters 50 adjacent to the plurality of inductive coupled plasma tubes 40 may be bent with an acute angle of less than 90°.

Supporters 20 may support the subject 12 to be processed. The subject 12 to be processed may have a high-performance thin film formed by the first and second plasmas 32 and 42 induced from the sputter gun 30 and the plurality of coupled plasma tubes 40.

As a result, since the thin film depositing apparatus according to embodiments of the present invention may manufacture a large quantity of high-performance thin films, productivity may be increased or maximized.

As mentioned above, according to embodiments of the present invention, a first plasma may be induced through a sputter gun. A more expanded second plasma than the first plasma may be induced through a plurality of inductive coupled plasma tubes. The second plasma may uniformly mix deposition particles sputtered from the first plasma. Additionally, the second plasma may increase an ionization rate of an inert gas charged by the first plasma and deposition particles. Accordingly, a thin film depositing apparatus according to embodiments of the present invention may increase or maximize productivity since it may mass-produce a high-performance thin film.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film depositing apparatus comprising:
a chamber where a process is performed on a subject to be processed;
a plurality of supporters supporting the subject to be processed in the chamber;
at least one sputter gun inducing a first plasma below or on the subject to be processed between the plurality of supporters; and
a plurality of inductive coupled plasma tubes inducing a more expanded second plasma than the first plasma between the sputter gun and the subject to be processed.

2. The thin film depositing apparatus of claim 1, wherein the plurality of inductive coupled plasma tubes comprise a rod electrode.

3. The thin film depositing apparatus of claim 2, wherein the supporters comprise a roller transferring the subject to be processed.

4. The thin film depositing apparatus of claim 3, wherein the roller is disposed parallel to the rod electrode.

5. The thin film depositing apparatus of claim 4, wherein the rod electrode guide the first plasma.

6. The thin film depositing apparatus of claim 1, further comprising a plurality of shutters between the plurality of inductive coupled plasma tubes and the subject to be processed.

7. The thin film depositing apparatus of claim 6, wherein the plurality of shutters expose the subject to be processed to the first plasma.

8. The thin film depositing apparatus of claim 7, wherein the plurality of shutters have end portions bent between the plurality of inductive coupled plasma tubes.

9. The thin film depositing apparatus of claim 8, wherein the end portions are bent with an acute angle when the sputter gun is one.

10. The thin film depositing apparatus of claim 1, further comprising a target generating deposition particles through the first plasma on the sputter gun.

11. The thin film depositing apparatus of claim 1, wherein the sputter gun has a width of 5 nm to 20 cm and a length of 30 cm to 300 cm.

12. The thin film depositing apparatus of claim 11, wherein when there are a plurality of sputter guns, they are disposed with a center distance of 5 cm to 20 cm.

13. The thin film depositing apparatus of claim 12, wherein the plurality of sputter guns are disposed to face each other at a tilt angle of 10° to 45°.
